(19) United States
(12) Patent Application Publication
(10) Pub. No.: US 2025/0250672 A1
(43) Pub. Date: Aug. 7, 2025

(54) METHOD OF MANUFACTURING METAL NITRIDE FILM

(71) Applicant: Miin-Jang CHEN, Taipei City (CN)

(72) Inventors: Miin-Jang CHEN, Taipei City (TW); Yu-Sen JIANG, Taipei City (TW); Guan-Cheng HUANG, Taipei City (TW); Fong-Jyun JHONG, Taipei City (TW)

(21) Appl. No.: 19/027,963

(22) Filed: Jan. 17, 2025

(30) Foreign Application Priority Data
Feb. 7, 2024 (TW) 113104992

(51) Int. Cl. C23C 16/455; C23C 16/34; C23C 16/44; H01L 21/02

(52) U.S. Cl. CPC C23C 16/45536; C23C 16/34; C23C 16/4408; H01L 21/02178; H01L 21/02186; H01L 21/02274; H01L 21/0228

(57) ABSTRACT

A method of manufacturing a metal nitride film is performed by at least one atomic layer deposition (ALD) cycle. Each of the at least one ALD cycle is firstly to perform at least one half cycle associated with a metal element, and in each half cycle, a precursor containing the metal element is supplied into a reaction chamber, and then a purge gas is selectively supplied into a reaction chamber, where a device is placed. Subsequently, a hydrogen plasma is firstly supplied into the reaction chamber, and then a nitrogen plasma is supplied into the reaction chamber. Alternatively, a nitrogen plasma is firstly supplied into the reaction chamber, and then a hydrogen plasma is supplied into the reaction chamber.

### CROSS-REFERENCE TO RELATED APPLICATION

This utility application claims priority to Taiwan Application Serial Number 113104992, filed Feb. 7, 2024, which is incorporated herein by reference.

### BACKGROUND OF THE INVENTION

### 1. Field of the Invention

The invention relates to a method of manufacturing a metal nitride film, and more particularly, to a method of manufacturing a metal nitride film with excellent crystalline quality by an atomic layer deposition process.

### 2. Description of the Prior Art

Metal nitride films have been widely used in devices in the semiconductor, optoelectronic, optical, micro-electromechanical, and many other fields due to their excellent electronic, optical, optoelectronic, and mechanical properties.

However, the crystalline quality of metal nitride films also affects their properties. Many researchers have been working on methods to produce metal nitride films with superior crystalline quality.

Currently, metal nitride films of superior crystalline quality can be produced by molecular beam epitaxy (MBE) and metal-organic chemical vapor deposition (MOCVD). However, the molecular beam epitaxy process is typically performed in a high vacuum or ultra-high vacuum (about 10′ Pa) environment. In addition, MOCVD processes typically require ultra-high temperatures (about 1000° C.) to grow high-quality gallium nitride, aluminum nitride, and other metal nitride films. However, thermal mismatch caused by different thermal expansion coefficients between the metal nitride film and the substrate can lead to thermal cracks in the metal nitride film. These factors result in difficulties in mass production using molecular beam epitaxy and metal-organic chemical vapor deposition processes.

Atomic layer deposition (ALD) has the following advantages: (1) atomic-level control of material formation; (2) more precise control of film thickness; (3) large-area mass production; (4) excellent uniformity; (5) excellent three-dimensional conformality; (6) pinhole-free structure; (7) low defect density; and (8) low deposition temperature, etc.

Compared to the MBE process, the ALD process does not require ultra-high vacuum, and can be operated at a working pressure of only about 60 Pa. The film deposition temperature of ALD is much lower than that of the MOCVD process.

However, the crystalline quality of metal nitride films produced by ALD of the prior art is still inferior to that of metal nitride films produced by MBE and MOCVD

In the prior art of producing metal nitride films by ALD, the conventional nitrogen source is either ammonia (NH₃) plasma or a mixture of nitrogen and hydrogen (N₂/H₂) plasma. However, there is still much room for improvement in the crystalline quality of metal nitride films produced by ALD.

### SUMMARY OF THE INVENTION

Accordingly, one scope of the invention is to provide a method of manufacturing a metal nitride film with excellent crystalline quality by an ALD process.

A method according to the first preferred embodiment is to manufacture a film of a metal nitride on a device. The metal nitride consists of a designated metal element. The method according to the first preferred embodiment is performed by at least one ALD cycle. Each ALD cycle includes the steps of: performing at least one half cycle associated with the designated metal element, and in each half cycle, supplying a precursor containing the designated metal element into a reaction chamber and then selectively supplying a purge gas into the reaction chamber in which the device is placed; supplying a hydrogen plasma into the reaction chamber; supplying a nitrogen plasma into the reaction chamber; and supplying the purge gas into the reaction chamber. In practical application, the designated metal element can be one in metal nitride films that have been widely used in those devices in semiconductor, optoelectronic, optical, micro-electromechanical, and other fields, or even silicon and germanium in Group IVA.

In one embodiment, the at least one ALD cycle is performed at a predetermined film deposition temperature and a predetermined working pressure. The predetermined film deposition temperature ranges from 100° C. to 700° C. The predetermined working pressure ranges from 0.1 Pa to 1000 Pa.

Further, in the method of manufacturing the film of the metal nitride on the device according to the first preferred embodiment, between the step of supplying the hydrogen plasma into the reaction chamber and the step of supplying the nitrogen plasma into the reaction chamber, each ALD cycle also includes the step of supplying the purge gas into the reaction chamber. In one embodiment, in the step of supplying the purge gas into the reaction chamber, the duration for supplying the purge gas is equal to or greater than 0 seconds.

In one embodiment, the film of the metal nitride is the AlNₓ film, and the film density of the AlNₓ film is equal to or greater than 2.95 g/cm³. The full width at half maximum (FWHM) of the X-ray rocking curve of an AlN(0002) diffraction peak of the AlNₓ film is equal to or less than 300 arcsec.

In one embodiment, the film of the metal nitride is the TiNₓ film, and the resistivity of the TiNₓ film is equal to or less than 10⁻⁶ Ω·m. The FWHM of the X-ray rocking curve of a TiN(111) diffraction peak of the TiNₓ film is equal to or less than 300 arcsec.

In one embodiment, the film of the metal nitride is the GaNₓ film, and the FWHM of the X-ray rocking curve of the GaN(0002) diffraction peak of the GaNₓ film is equal to or less than 300 arcsec.

A method according to the second preferred embodiment is to manufacture a film of a metal nitride on a device. The metal nitride consists of a designated metal element. The method according to the second preferred embodiment is performed by at least one ALD cycle. Each ALD cycle includes the steps of: performing at least one half cycle associated with the designated metal element, and in each half cycle, supplying a precursor containing the designated metal element into a reaction chamber and then selectively supplying a purge gas into the reaction chamber in which the device is placed; supplying a nitrogen plasma into the reaction chamber; supplying a hydrogen plasma into the reaction chamber; and supplying the purge gas into the reaction chamber. In practical application, the designated metal element can be one in the metal nitride films that have been widely used in those devices in semiconductor, optoelectronic, optical, micro-electromechanical, and other fields, or even silicon and germanium in Group IVA.

Further, in the method of manufacturing the film of the metal nitride on the device according to the second preferred embodiment, between the step of supplying the nitrogen plasma into the reaction chamber and the step of supplying the hydrogen plasma into the reaction chamber, each ALD also includes the step of supplying the purge gas into the reaction chamber. In one embodiment, in the step of supplying the purge gas into the reaction chamber, the duration for supplying the purge gas is equal to or greater than 0 seconds.

Distinguishable from the metal nitride film manufactured by the ALD process using a mixture of nitrogen and hydrogen plasma in the prior art, the method according to the invention not only manufactures the metal nitride film by an ALD process, but also supplies the hydrogen plasma and the nitrogen plasma at different times in a time sequence. The metal nitride film manufactured by the method according to the invention has excellent crystalline quality.

The advantage and spirit of the invention may be understood by the following recitations together with the appended drawings.

### BRIEF DESCRIPTION OF THE APPENDED DRAWINGS

FIG. 1 is a flowchart of each of the at least one ALD cycle utilized in the method according to the first preferred embodiment of the invention.

FIG. 2 is a flowchart of each of the at least one ALD cycle utilized in the method according to the second preferred embodiment of the invention.

FIG. 3 shows the ω-2θ X-ray diffraction (XRD) patterns of the AlNₓ films grown on a (0001) sapphire substrate in the first example of the invention and a comparative example.

FIG. 4 shows the high-resolution transmission electron microscopy (HRTEM) image of an AlNₓ film in the first example of the invention, in which the hydrogen plasma is firstly supplied for 40 seconds and then the nitrogen plasma is supplied for 40 seconds in each ALD cycle.

FIG. 5 shows a high angle annular dark-field scanning transmission electron microscopy (HAADF-STEM) image of an AlNₓ film in the first example of the invention, in which the hydrogen plasma is firstly supplied for 40 seconds and then the nitrogen plasma is supplied for 40 seconds in each ALD cycle.

FIG. 6 shows the ω-2θ XRD patterns of the TiNₓ films grown on a (0001) sapphire substrate in the second example of the invention and a comparative example.

FIG. 7 shows the carbon content and resistivity of the TiNₓ films in the second example of the invention and the comparative example.

FIG. 8 shows the ω-2θ XRD patterns of the TiNₓ films grown on a (0001) sapphire substrate by firstly supplying the nitrogen plasma for 40 seconds and then supplying the hydrogen plasma with different time durations to perform each ALD cycle in the third example of the invention.

FIG. 9 shows the carbon content and resistivity of the TiNₓ films in the third example of the invention and the comparative example.

FIG. 10 shows an HRTEM image and nanobeam electron diffraction patterns of the TiNₓ film grown on a (0001) sapphire substrate by firstly supplying the nitrogen plasma for 40 seconds and then supplying the hydrogen plasma for 60 seconds in each ALD cycle, in the third example of the invention.

FIG. 11 shows the ω-2θ XRD patterns of the TiNₓ films grown on the (0001) sapphire substrate by supplying hydrogen plasma and nitrogen plasma at different times in each ALD cycle, in the fourth example of the present invention, as well as the comparative example.

FIG. 12 shows the ω-2θ XRD patterns of the GaNₓ films grown on (0001) sapphire substrate in the fifth example of the invention as well as a comparative example.

### DETAILED DESCRIPTION OF THE INVENTION

Some preferred embodiments and practical applications of this present invention would be explained in the following paragraph, describing the characteristics, spirit, and advantages of the invention.

A method according to the first preferred embodiment is to manufacture a film of a metal nitride on a device. The metal nitride consists of a designated metal element. The method according to the first preferred embodiment is performed by at least one ALD cycle. In practical application, the designated metal element can be one in metal nitride films that have been widely used in those devices in semiconductor, optoelectronic, optical, micro-electromechanical, and other fields, or even silicon and germanium in Group IVA. That is to say, the film of the metal nitride can be formed of AlNₓ, TiNₓ, GaNₓ, InNₓ, HfNₓ, ZrNₓ, SiNₓ, GeNₓ, LaNₓ, TaNₓ, NbNₓ, BNₓ, WNₓ, MoNₓ and the like, where 0.5≤x≤1.5.

It should be emphasized that the device used in the method according to the first preferred embodiment of the invention can be a finished product or a semi-finished product of devices in various fields such as semiconductor, optoelectronic, optical, micro-electromechanical fields, etc., and can also be crystalline, non-crystalline, or semi-crystalline substrates. It should be noted that each ALD cycle consists of two half cycles. The ALD process is utilized to produce metal nitride films. Basically, each ALD cycle consists of two half cycles, where the first half cycle supplies a precursor containing the designated metal element and a purge gas into the reaction chamber, and the second half cycle supplies a reactant containing a nitrogen plasma and a hydrogen plasma and the purge gas into the reaction chamber. It has been revealed that multiple first half cycles of supplying the precursor containing the designated metal element and the purge gas have been performed before the second half cycle of supplying the reactant containing the nitrogen plasma and the hydrogen plasma and the purge gas is performed. The execution of multiple first half cycles for supplying the precursor containing the designated metal element and the purge gas may be performed either as a single supply of the precursor containing the designated metal element followed by the supply of the purge gas, or as multiple supplies of the precursor containing the designated metal element followed by the supply of the purge gas, provided that the purge gas is supplied as the last sub-step of the multiple first half cycles. Therefore, in each of a plurality of first half cycles in which the precursor containing the designated metal element and the purge gas are supplied, the precursor containing the designated metal element is supplied firstly, and then the purge gas is selectively supplied.

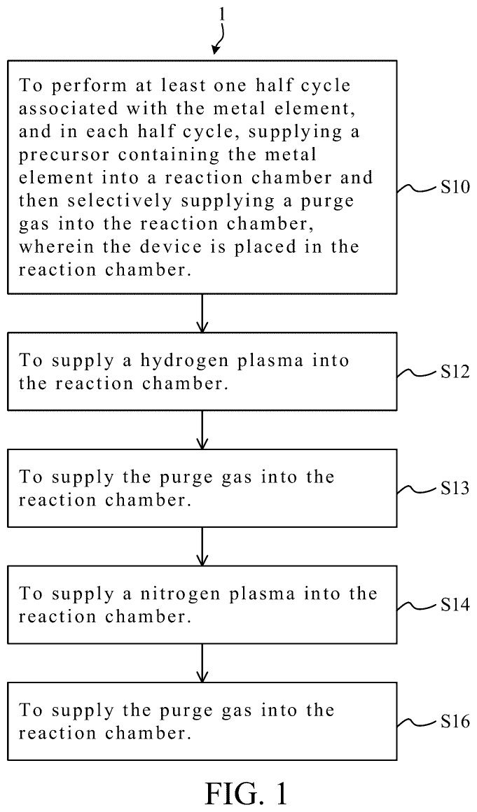

Referring to FIG. 1, FIG. 1 is a flowchart of each of the at least one ALD cycle 1 utilized by the method according to the first preferred embodiment of the invention.

As shown in FIG. 1, each ALD cycle 1, firstly, performs step S10 to perform at least one half cycle associated with the designated metal element. In each half cycle associated with the designated metal element, a precursor containing the designated metal element is supplied into a reaction chamber, and then selectively a purge gas is supplied into the reaction chamber in which the device is placed. In one embodiment, the purge gas can be an inert gas (e.g., argon, helium) or a non-reactive gas (e.g., nitrogen). In practical application, the purge gas can also be used as a carrier gas for precursors and plasmas.

Taking HfNₓ as an example, the precursor supplying the Hf element can be HfCl₄, HfI₄, HfCl₂[N(SiMe₃)₂]₂, HfCp₂Me₂, HfCp₂Cl₂, Hf(CpMe)₂Me₂, Hf(CpMe)₂(OMe)Me, Hf(CpMe)₂(OⁱPr)Me, Hf(CpMe)₂(mmp)Me, Hf(Cp)(NMe₂)₃, Hf(CpMe)(NMe₂)₃, Hf(Cp₂CMe₂)Me₂, Hf(Cp₂CMe₂)Me(OMe), Hf(OⁱPr)₄, Hf(O^{t}Bu)₄, Hf(O^{t}Bu)₂(mmp)₂, Hf(O^{t}Bu)(NEtMe)₃, Hf(mmp)₄, Hf(mp)₄, Hf(ONEt₂)₄, Hf(NMe₂)₄, Hf(NEt₂)₄, Hf(NEtMe)₄, Hf[N(SiMe₃)₂]₂Cl₂, Hf(NO₃)₄, and the like.

Taking ZrNₓ as an example, the precursor supplying the Zr element can be ZrCl₄, ZrI₄, ZrCp₂Cl₂, ZrCp₂Me₂, ZrCp₂Me(OMe), ZrCp(NMe₂)₃, Zr(CpMe)₂Me₂, Zr(CpMe)₂Me(OMe), Zr(CpMe)(NMe₂)₃, Zr(CpEt)(NMe₂)₃, Zr(Cp₂CMe₂)Me₂, Zr(Cp₂CMe₂)Me(OMe), Zr(OⁱPr)₄, Zr(OⁱPr)₂(dmae)₂, Zr(O^{t}Bu)₄, Zr(O^{t}Bu)₂(dmae)₂, Zr(dmae)₄, Zr(thd)₄, Zr(NMe₂)₄, Zr(NEt₂)₄, Zr(NEtMe)₄, Zr[N(SiMe₃)₂]₂Cl₂, Zr(MeAMD)₄, and the like.

Taking AlNₓ as an example, the precursor supplying the Al element can be AlCl₃, AlBr₃, Al(CH₃)₃(trimethylaluminum, TMA), AlMe₂Cl, AlMe₂OⁱPr, AlEt₃, Al(OEt)₃, Al(OnPr)₃, Al(mmp)₃, Al(NEt₂)₃, Al(NiPr₂)₃, Al(ⁱPrAMD)Et₂, and the like.

Taking TiNₓ as an example, the precursor supplying the Ti element can be TiF₄, TiCl₄, TiI₄, Ti[N(CH₃)₂]₄ (tetrakis(dimethylamino)titanium, TDMAT), Ti[N(C₂H₅)₂]₄, Ti(CpMe₅)(OMe)₃, Ti(CpMe)(OⁱPr)₃, Ti(OMe)₄, Ti(OEt)₄, Ti(OⁱPr)₄, Ti(OⁱPr)₂(dmae)₂, Ti(OⁱPr)₂(thd)₂, Ti(trhd)₂(O(CMe₂Et)₂, Ti(OBu)₄, Ti(NMe₂)₄, TiCp₂((ⁱPrN)₂C(NHⁱPr)), and the like.

Taking LaNₓ as an example, the precursor supplying the La element can be La(thd)₃, La[N(SiMe₃)₂]₃, La(ⁱPrAMD)₃, La(ⁱPrfAMD)₃, La(Cp)₃, La(CpEt)₃, La(CpⁱPr)₃, and the like.

Taking SiNₓ as an example, the precursor supplying the Si element can be SiCl₄, Si₂Cl₆, SiCl₃H, SiCl₂H₂, SiH₄, Si(OMe)₄, Si(OEt)₄, Si(OEt)₃((CH₂)₃NH₂), Si(O^{t}Pe)₃OH, HMDS, SiH₂(N(CH₃)₂)₂, SiH₂(NH^{t}Bu)₂, SiH₂(NEt₂)₂, SiH(N(CH₃)₂)₃, Si(NCO)₄, MeOSi(NCO)₃, (SiH₃)₃N (trisilylamine, TSA), and the like.

Taking GeNₓ as an example, the precursor supplying the Ge element can be Ge(NMe₂)₄(Me=CH₃, tetrakis(dimethylamino)germane, TDMAGe).

Taking YNₓ as an example, the precursor supplying the Y element can be Y(thd)₃, YCp₃, Y(CpMe)₃, Y(CpEt)₃, Y(ⁱPrAMD)₃, and the like.

Taking GaNₓ as an example, the precursors supplying the Ga element can be GaCl₃, GaBr₃, Gal₃, Ga(CH₃)₃(trimethyl gallium, TMG) Ga(C₂H₅)₃(triethylgallium, TEG), and the like.

Next, each ALD cycle 1 performs step S12 to supply a hydrogen plasma into the reaction chamber. Then, each ALD cycle 1 performs step S14 to supply a nitrogen plasma into the reaction chamber. Finally, each ALD cycle 1 performs step S16 to supply the purge gas into the reaction chamber.

In one embodiment, the at least one ALD cycle 1 is performed at a predetermined film deposition temperature and a predetermined working pressure. The predetermined film deposition temperature ranges from 100° C. to 700° C. The predetermined working pressure ranges from 0.1 Pa to 1000 Pa.

It should be emphasized that different from the ALD process of the prior art using a mixture of nitrogen and hydrogen (N₂/H₂) plasma, the method according to the first preferred embodiment of the invention is based on the ALD process and introduces the hydrogen plasma at different times during the ALD process to participate in the chemical reaction in order to produce the film of the metal nitride with excellent crystalline quality. The films of the metal nitrides, manufactured according to the method of the invention, have excellent crystalline qualities and excellent properties, as demonstrated by several examples of the invention hereinafter. In this context, the method utilized in the invention is referred to as hydrogen-manipulated atomic layer epitaxy. The incorporation of hydrogen plasma at specific times in each ALD cycle is believed to be a key factor in promoting epitaxial growth, thereby enabling atomic layer epitaxial crystallization of metal nitrides at low growth temperatures. In particular, the metal nitride epitaxial layer realized according to the method of the first preferred embodiment of the invention can be produced in a low vacuum condition with good thickness uniformity over a large area, which is a major advantage for practical applications as well as for mass production.

Also as shown in FIG. 1, in the method of manufacturing the film of the metal nitride on the device according to the first preferred embodiment, between step S12 of supplying the hydrogen plasma into the reaction chamber and step S14 of supplying the nitrogen plasma into the reaction chamber, each ALD cycle 1 also performs step S13 of supplying the purge gas into the reaction chamber. In one embodiment, in step S13 of supplying the purge gas into the reaction chamber, the duration for supplying the purge gas is equal to or greater than 0 seconds.

In one embodiment, the film of the metal nitride is the AlNₓ film, and the film density of the AlNₓ film is equal to or greater than 2.95 g/cm³. It should be noted that the theoretical density of AlN is about 3.26 g/cm³. The full width at half maximum (FWHM) of the X-ray rocking curve of an AlN(0002) diffraction peak of the AlNₓ film is equal to or less than 300 arcsec.

In one embodiment, the film of the metal nitride is the TiNₓ film, and the resistivity of the TiNₓ film is equal to or less than 10⁻⁶ Ω·m. The FWHM of the X-ray rocking curve of a TiN(111) diffraction peak of the TiNₓ film is equal to or less than 300 arcsec.

In one embodiment, the film of the metal nitride is the GaNₓ film, and the FWHM of the X-ray rocking curve of a GaN(0002) diffraction peak of the GaNₓ film is equal to or less than 300 arcsec.

In addition, the method of manufacturing the film of the metal nitride on the device according to the first preferred embodiment of the invention can change precursors containing different metal elements after performing a single or multiple ALD cycles 1. Therefore, the method according to the first preferred embodiment of the invention can produce a film of the metal nitrides containing multiple metal elements.

A method according to the second preferred embodiment is to manufacture a film of a metal nitride on a device. The metal nitride consists of a designated metal element. The method according to the second preferred embodiment is performed by at least one ALD cycle 2. The selection of the designated metal elements and the types of metal nitrides are the same as those described above, and will not be described in detail herein.

It should be emphasized that similarly, the device used in the method according to the second preferred embodiment of the invention can be a finished product or a semi-finished product of devices in various fields such as semiconductor, optoelectronic, optical, micro-electromechanical fields, etc., and can also be crystalline, non-crystalline, or semi-crystalline substrates.

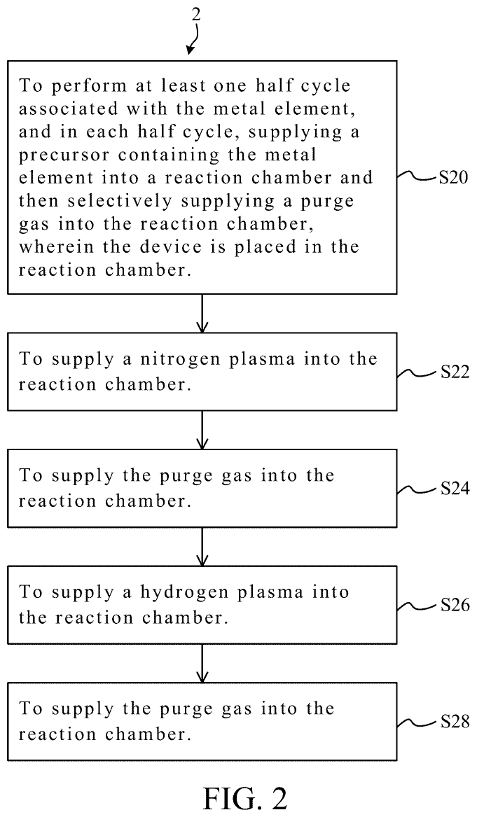

Referring to FIG. 2, FIG. 2 is a flowchart of each of the at least one ALD cycle 2 utilized by the method according to the second preferred embodiment of the invention.

As shown in FIG. 2, each ALD cycle 2, firstly, performs step S20 to perform at least one half cycle associated with the designated metal element. In each half cycle associated with the designated metal element, a precursor containing the designated metal element is supplied into a reaction chamber and then selectively a purge gas is supplied into the reaction chamber in which the device is placed. In one embodiment, the purge gas can be an inert gas (e.g., argon, helium) or a non-reactive gas (e.g., nitrogen). In practical application, the purge gas can also be used as a carrier gas for precursors and plasmas.

Next, each ALD cycle 2 performs step S22 to supply a nitrogen plasma into the reaction chamber. Then, each ALD cycle 2 performs step S26 to supply a hydrogen plasma into the reaction chamber. Finally, each ALD cycle 2 performs step S28 to supply the purge gas into the reaction chamber.

In one embodiment, the at least one ALD cycle 2 is performed at a predetermined film deposition temperature and a predetermined working pressure. The predetermined film deposition temperature ranges from 100° C. to 700° C. The predetermined working pressure ranges from 0.1 Pa to 1000 Pa.

Also as shown in FIG. 2, in the method of manufacturing the film of the metal nitride on the device according to the second preferred embodiment, between step S22 of supplying the nitrogen plasma into the reaction chamber and step S26 of supplying the hydrogen plasma into the reaction chamber, each ALD cycle 2 also performs step S24 of supplying the purge gas into the reaction chamber. In one embodiment, in step S24 of supplying the purge gas into the reaction chamber, the duration for supplying the purge gas is equal to or greater than 0 seconds.

In one embodiment, the film of the metal nitride is the AlNₓ film, and the film density of the AlNₓ film is equal to or greater than 2.95 g/cm³. It should be noted that the theoretical density of AlN is about 3.26 g/cm³. The FWHM of the X-ray rocking curve of an AlN(0002) diffraction peak of the AlNₓ film is equal to or less than 300 arcsec.

In one embodiment, the film of the metal nitride is the TiNₓ film, and the resistivity of the TiNₓ film is equal to or less than 10⁻⁶ Ω·m. The FWHM of the X-ray rocking curve of a TiN(111) diffraction peak of the TiNₓ film is equal to or less than 300 arcsec.

In one embodiment, the film of the metal nitride is the GaNₓ film, and the FWHM of the X-ray rocking curve of a GaN(0002) diffraction peak of the GaNₓ film is equal to or less than 300 arcsec.

In addition, the method of manufacturing the film of the metal nitride on the device according to the second preferred embodiment of the invention can change precursors containing different metal elements after performing a single or multiple ALD cycles 2. Therefore, the method according to the second preferred embodiment of the invention can produce a film of the metal nitrides containing multiple metal elements.

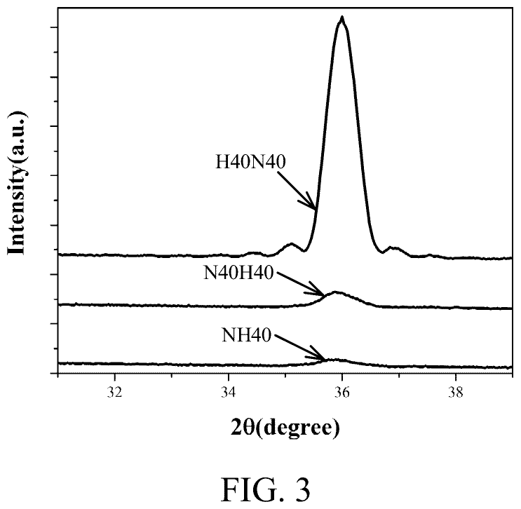

In the first example of the invention, an AlNₓ film is grown on a (0001) sapphire substrate by the method according to the invention. In the first example of the invention, TMA is utilized as a precursor for supplying the Al element. In the first example of the invention, a hydrogen plasma and a nitrogen plasma are supplied at different times to perform each ALD cycle to form the AlNₓ film. Referring to FIG. 3, FIG. 3 shows the ω-2θ XRD patterns of the AlNₓ film produced in the first example of the invention.

In FIG. 3, the specimen labeled as “N40H40” means that the nitrogen plasma is firstly supplied for 40 seconds and then the hydrogen plasma is supplied for 40 seconds, with the purge gas being supplied for 10 seconds between the supply of the nitrogen plasma and the supply of the hydrogen plasma. The specimen labeled as “H40N40” means that the hydrogen plasma is firstly supplied for 40 seconds and then the nitrogen plasma is supplied for 40 seconds, with the purge gas being supplied for 10 seconds between the hydrogen plasma and the nitrogen plasma. In the first example of the invention, the power of the radio frequency at 13.5 MHz used to generate the plasma is 300 W, the film deposition temperature is 300° C., and the working pressure is about 60 Pa.

As a comparative example, FIG. 3 shows the ω-2θ XRD pattern of the AlNₓ film produced by supplying a mixture of nitrogen and hydrogen (N₂/H₂) plasma for 40 seconds to perform each ALD cycle, and the specimen is labeled as “NH40” in FIG. 3. As can be seen from FIG. 3, the signal intensity of the AlN(0002) diffraction peak of the NH40 sample is extremely weak. The AlN(0002) diffraction peak of the AlNₓ film (N40H40) produced by supplying the nitrogen plasma followed by supplying the hydrogen plasma has a more pronounced signal intensity. The AlN(0002) diffraction peak of the AlNₓ film (H40N40) produced by supplying the hydrogen plasma followed by supplying the nitrogen plasma has the highest signal intensity. It is obvious that the first example of the invention can significantly improve the crystallization quality of the AlNₓ film by separating the supply of the hydrogen plasma from the nitrogen plasma in each ALD cycle, and in particular, by supplying the hydrogen plasma followed by supplying the nitrogen plasma in the time sequence. In addition, the X-ray rocking curve of an AlN(0002) diffraction peak of the AlNₓ film labeled as “H40N40” has a low FWHM of about 171 arcsec. It is indicated that the AlNₓ film produced by the method of the invention has excellent crystalline quality.

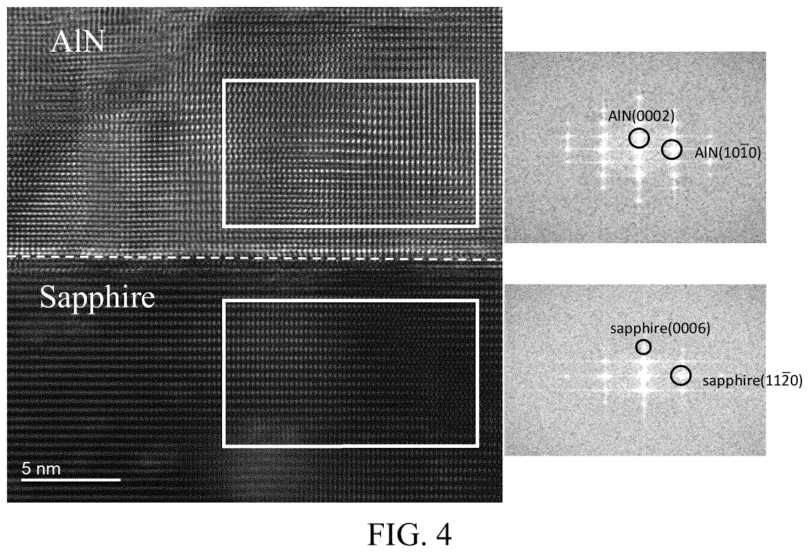

Referring to FIG. 4, FIG. 4 shows the HRTEM image of the AlNₓ film labeled as “H40N40”, which is produced by supplying the hydrogen plasma followed by supplying the nitrogen plasma in the first example of the invention. According to the HRTEM image, the reciprocal lattice points are further obtained by a fast Fourier transformation, which is also shown in FIG. 4. The results shown in FIG. 4 confirm that the first example of the invention, in which the AlNₓ film (H40N40) is produced by supplying the hydrogen plasma followed by supplying the nitrogen plasma, has a very good crystalline quality, and its epitaxial relationship with the (0001) sapphire substrate is [0002]_{AIN}//[0006]ₛₐₚₚₕᵢᵣₑ and [101̅0]_{AIN}//[112̅0]ₛₐₚₚₕᵢᵣₑ.

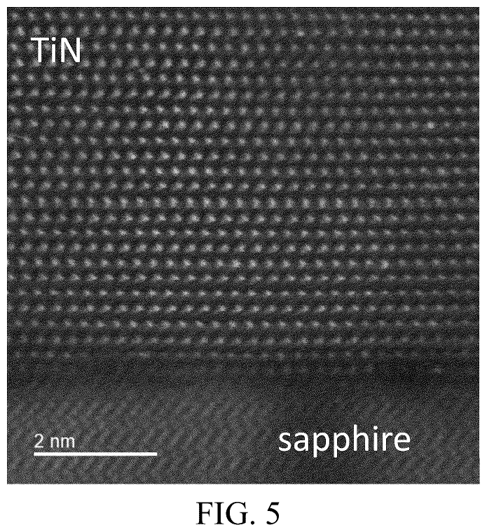

Referring to FIG. 5, FIG. 5 shows a HAADF-STEM image of an AlNₓ film (H40N40) produced by supplying the hydrogen plasma followed by supplying the nitrogen plasma in the first example of the invention, which clearly shows the clear and well-organized atomic arrangement and excellent crystallization quality of the AlNₓ film.

The density of the AlNₓ film (H40N40) produced by supplying the hydrogen plasma followed by supplying the nitrogen plasma in the first example of the invention, as measured by the X-ray reflectivity (XRR) method, is listed in Table 1. The density of the AlNₓ film (NH40) of the comparative example fabricated using a mixture of nitrogen and hydrogen (N₂/H₂) plasma is also listed in Table 1.

TABLE 1

| process condition of | |
|---|---|
| fabricating film | density (g/cm³) |
| NH40 | 2.94 |
| H40N40 | 3.13 |

The results in Table 1 show that the density of the AlNₓ film (H40N40) in the first example of the invention, which is produced by supplying the hydrogen plasma followed by supplying the nitrogen plasma, is 3.13 g/cm³, which is higher than 2.95 g/cm³, and is quite close to the theoretical density of AlN (about 3.26 g/cm³). The AlNₓ film (NH40) of the comparative example is produced using a mixture of nitrogen and hydrogen (N₂/H₂) plasma, which has a density of only 2.94 g/cm³. According to the first example of the invention described above, it is sufficient to demonstrate that the method according to the invention is the atomic layer epitaxy based on the hydrogen manipulation of chemical reactions during the ALD process, and that the metal nitride epitaxial films of higher density can be produced.

The second example of the invention is the growth of a TiNₓ film on a (0001) sapphire substrate by the method according to the invention. In the second example of the invention, TDMAT is utilized as a precursor for supplying Ti element. In the second example of the invention, the nitrogen plasma is firstly supplied and then the hydrogen plasma is supplied in a time sequence to perform each ALD cycle to produce the TiNₓ film.

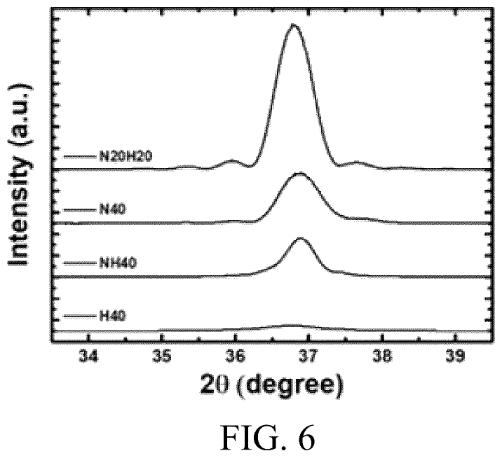

Referring to FIG. 6, FIG. 6 shows the ω-2θ XRD patterns of the TiNₓ film produced in the second example of the invention. In FIG. 6, the specimen labeled as “N20H20” represents that the nitrogen plasma is firstly supplied for 20 seconds and then the hydrogen plasma is supplied for 20 seconds, with the purge gas being supplied for 10 seconds between the supply of the nitrogen plasma and the supply of the hydrogen plasma. In the second example of the invention, the radio frequency power used to generate the plasma is 300 W, the film deposition temperature is 300° C., and the working pressure is about 80 Pa. As a comparative example, the ω-2θ XRD pattern of the TiNₓ film produced by supplying a mixture of nitrogen and hydrogen (N₂/H₂) plasma for 40 seconds to perform each ALD cycle is also shown in FIG. 6, and the specimen is labeled as “NH40” in FIG. 6. The ω-2θ XRD pattern of the TiNₓ film produced by supplying only the hydrogen plasma for 40 seconds to perform each ALD cycle is also shown in FIG. 6, and the specimen is labeled as “H40” in FIG. 6. The ω-2θ XRD pattern of the TiNₓ film produced by supplying only the nitrogen plasma for 40 seconds to perform an ALD cycle is also shown in FIG. 6, and the specimen is labeled as “N40” in FIG. 6. The results in FIG. 6 show that the TiN(111) diffraction peak labeled as “H40” has a very weak signal intensity, the TiN(111) diffraction peaks labeled as “N140” and “N40” have a slightly higher signal intensity, and the TiN(111) diffraction peak labeled as “N20H20” has the highest signal intensity.

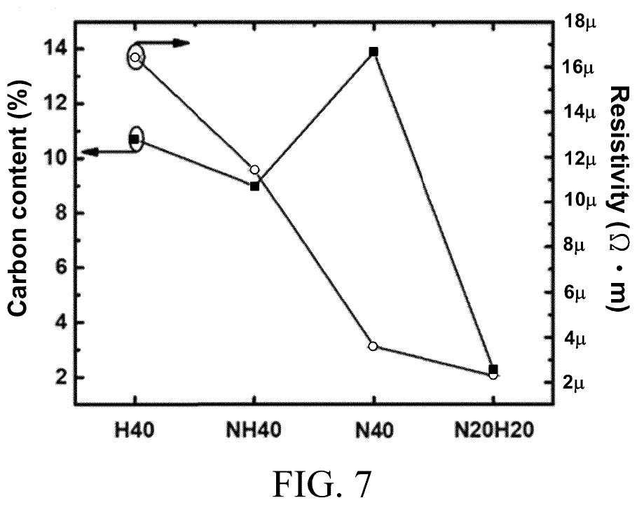

Referring to FIG. 7, FIG. 7 shows the measured carbon contents and resistivities of the TiNₓ films produced in the second example of the invention and its comparative examples, where the carbon source is TDMAT. The results in FIG. 7 show that the TiNₓ film labeled as “N20H20” has both the lowest resistivity and the lowest carbon content.

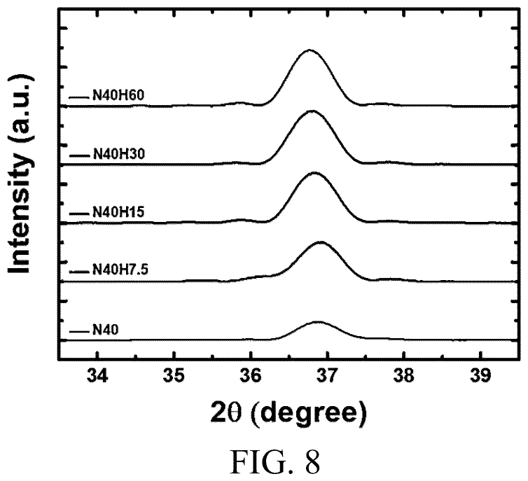

The third example of the invention is the growth of a TiNₓ film on a (0001) sapphire substrate by the method according to the invention. In the third example of the invention, TDMAT is utilized as a precursor for supplying the Ti element. In the third example of the invention, a nitrogen plasma is firstly supplied for 40 seconds and then a hydrogen plasma is supplied for different durations, with a purge gas being supplied for 10 seconds between the supply of the nitrogen plasma and the supply of the hydrogen plasma to perform each ALD cycle to produce the TiNₓ film. Referring to FIG. 8, FIG. 8 shows the ω-2θ XRD patterns of the TiNₓ film produced in the third example of the invention. In FIG. 8, the specimen labeled as “N40H7.5” means that the nitrogen plasma is firstly supplied for 40 seconds and then the hydrogen plasma is supplied for 7.5 seconds. The specimen labeled as “N40H15” means that the nitrogen plasma is firstly supplied for 40 seconds and then the hydrogen plasma is supplied for 15 seconds. The specimen labeled as “N40H30” means that the nitrogen plasma is firstly supplied for 40 seconds and then the hydrogen plasma is supplied for 30 seconds. The specimen labeled as “N40H60” means that the nitrogen plasma is firstly supplied for 40 seconds and then the hydrogen plasma is supplied for 60 seconds. In the third example of the invention, the radio frequency power used to generate the plasma is 300 W, the film deposition temperature is 300° C., and the working pressure is about 80 Pa. The duration for supplying the purge gas is 10 seconds between the supply of the nitrogen plasma and the supply of the hydrogen plasma. As a comparative example, the ω-2θ XRD pattern of the TiNₓ film produced by supplying only the nitrogen plasma for 40 seconds to perform each ALD cycle is also shown in FIG. 8, and the specimen is labeled as “N40” in FIG. 8. The results in FIG. 8 show that the signal intensities of the TiN(111) diffraction peaks labeled as “N40H7.5”, “N40H15”, “N40H30” and “N40H60” are all higher than that of the TiN(111) diffraction peak labeled as “N40”. This indicates that the participation of hydrogen plasma can effectively enhance the crystalline quality of the TiNₓ films. In addition, the FWHM of the X-ray rocking curve of the TiN(111) diffraction peak of the TiNₓ film labeled as “N40H60” is low of only about 202 arcsec. This indicates that the TiNₓ film produced by the method of the invention has excellent crystalline quality.

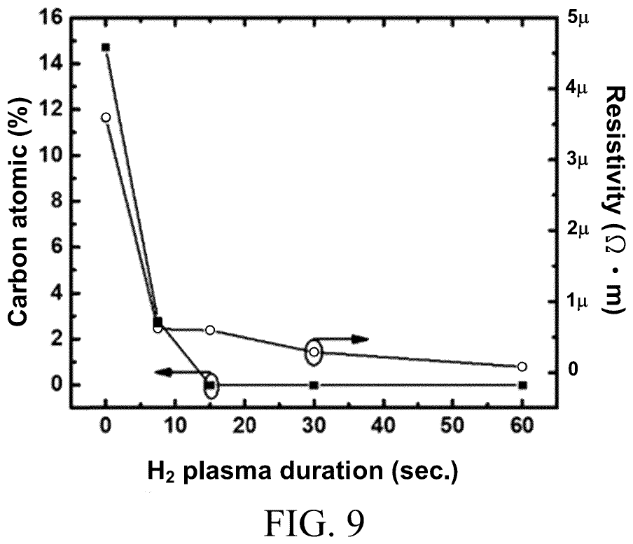

Referring to FIG. 9, FIG. 9 shows the measured carbon contents and resistivities of the TiNₓ films produced in the third example of the invention and the comparative example, where the carbon source is TDMAT. The results in FIG. 9 show that as the hydrogen plasma treatment time is increased, the carbon contents and resistivities of the TiNₓ films decrease significantly. A minimum resistivity as low as 8.2×10⁻⁸Ω·m has been achieved in the TiNₓ film labeled as “N40H60”. This can be attributed to the excellent crystalline quality and low carbon content of the TiNₓ film labeled as “N40H60”.

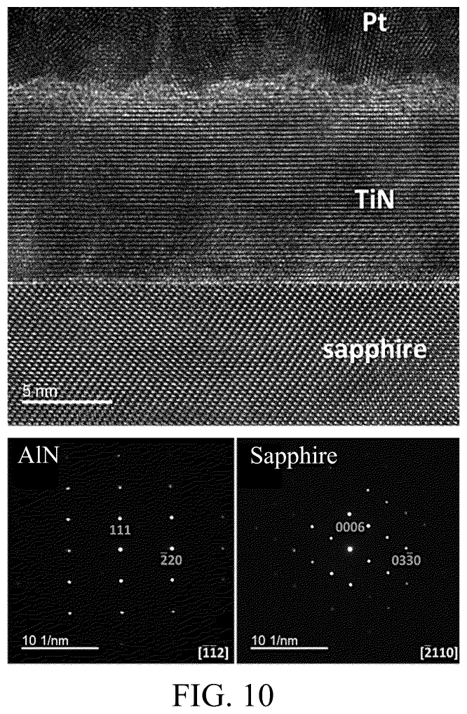

Referring to FIG. 10, FIG. 10 is an HRTEM image of the TiNₓ film labeled as “N40H60” produced in the third example of the invention, in which the nanobeam electron diffraction patterns of the TiNₓ film and the (0001) sapphire substrate are also shown in FIG. 10. The results shown in FIG. 10 confirm that the TiNₓ film labeled as “N40H60” produced in the third example of the invention has a very good crystalline quality, and its epitaxial relationship with the (0001) sapphire substrate is [111]_{TiN}//[0001]ₛₐₚₚₕᵢᵣₑ and [2̅20]_{TiN}//[033̅0]ₛₐₚₚₕᵢᵣₑ.

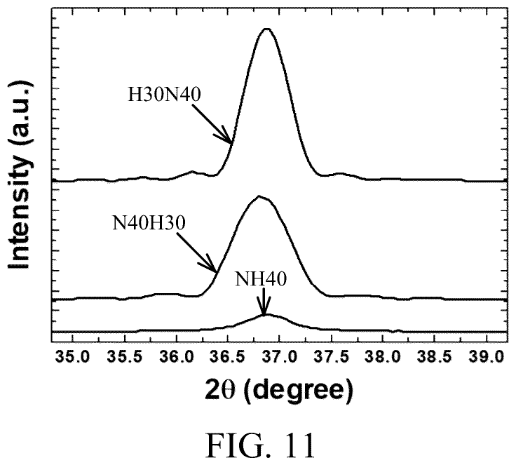

The fourth example of the invention is the growth of a TiNₓ film on a (0001) sapphire substrate by the method according to the invention. In the fourth example of the invention, TDMAT is utilized as a precursor for supplying the Ti element. In the fourth example of the invention, the hydrogen plasma and the nitrogen plasma are supplied at different times to perform each ALD cycle to produce TiNₓ films. Referring to FIG. 11, FIG. 11 shows the ω-2θ XRD patterns of the TiNₓ films produced in the fourth example of the invention. In FIG. 11, the specimen labeled as “H30N40” means that the hydrogen plasma is firstly supplied for 30 seconds and then the nitrogen plasma is supplied for 40 seconds, with the purge gas being supplied for 10 seconds between the supply of the hydrogen plasma and the supply of the nitrogen plasma. The specimen labeled as “N40H30” means that the nitrogen plasma is firstly supplied for 40 seconds and then the hydrogen plasma is supplied for 30 seconds, with the purge gas being supplied for 10 seconds between the supply of the hydrogen plasma and the supply of the nitrogen plasma. In the fourth example of the invention, the radio frequency power used to generate the plasma is 300 W, the film deposition temperature is 300° C., and the working pressure is about 80 Pa. As a comparative example, the ω-2θ XRD pattern of the TiNₓ film produced by supplying a mixture of nitrogen and hydrogen (N₂/H₂) plasma for 40 seconds to perform each ALD cycle is also shown in FIG. 11, and the comparative example is labeled as “N140” in FIG. 11. The results in FIG. 11 show that the signal intensity of the TiN(111) diffraction peak labeled as “N140” is very weak. The signal intensity of the TiN(111) diffraction peak labeled as “N40H30” is much higher than that of the TiN(111) diffraction peak labeled as “NH40”. The signal intensity of the TiN(111) diffraction peak labeled as “H30N40” is obviously higher than that of the TiN(111) diffraction peak labeled as “N40H30”. To summarize the above observations, the crystalline quality of the TiNₓ films can be improved by separating the supply of hydrogen plasma and nitrogen plasma in the time sequence to perform each ALD cycle. In particular, the crystalline quality of the TiNₓ films can be significantly improved by firstly supplying the hydrogen plasma followed by supplying the nitrogen plasma.

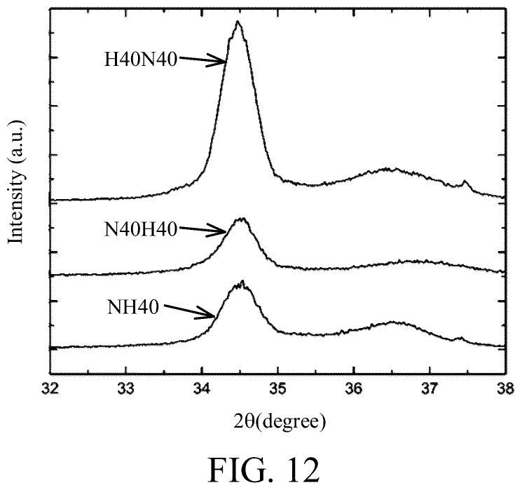

The fifth example of the invention is the growth of a GaNₓ film on a (0001) sapphire substrate by the method according to the invention. In the fifth example of the invention, TMG is utilized as a precursor for supplying the Ga element. In the fifth example of the invention, the hydrogen plasma and the nitrogen plasma are supplied at different times to perform each ALD cycle to produce GaNₓ films. Referring to FIG. 12, FIG. 12 shows the ω-2θ XRD patterns of GaNₓ films produced in the fifth example of the invention. In FIG. 12, the specimen labeled as “H40N40” means that the hydrogen plasma is firstly supplied for 40 seconds and then the nitrogen plasma is supplied for 40 seconds, with the purge gas being supplied for 10 seconds between the supply of the hydrogen plasma and the supply of the nitrogen plasma. The specimen labeled as “N40H40” means that the nitrogen plasma is firstly supplied for 40 seconds and then the hydrogen plasma is supplied for 40 seconds, with the purge gas being supplied for 10 seconds between the supply of the hydrogen plasma and the supply of the nitrogen plasma. In the fifth example of the invention, the radio frequency power used to generate the plasma is 300 W, the film deposition temperature is 300° C., and the working pressure is about 60 Pa. As a comparative example, the ω-2θ XRD pattern of the GaNₓ film produced by supplying a mixture of nitrogen and hydrogen (N₂/H₂) plasma for 40 seconds to perform each ALD cycle is also shown in FIG. 12, and the specimen is labeled as “NH40” in FIG. 12. The results in FIG. 12 show that the GaN(0002) diffraction peak labeled as “NH40” is clearly detectable. The signal intensity of the GaN(0002) diffraction peak labeled as “N40H40” is very close to that of the GaN(0002) diffraction peak labeled as “NH40”. The signal intensity of the GaN(0002) diffraction peak labeled as “H40N40” is significantly higher than that of the GaN(0002) diffraction peak labeled as “N40H40”. In addition, the X-ray rocking curve of the GaN(0002) diffraction peak of the GaNₓ film labeled as “H40N40” has a low FWHM of approximately 210 arcsec. This indicates that the GaNₓ film produced by the method of the invention has excellent crystalline quality. To summarize the above observations, the crystalline quality of GaNₓ films can be improved by separating the supply of hydrogen plasma and nitrogen plasma in the time sequence to perform each ALD cycle. In particular, the crystalline quality of the GaNₓ films can be significantly improved by firstly supplying the hydrogen plasma followed by supplying the nitrogen plasm.

In addition, the overall thermal resistance of the film is composed of the thermal resistance of the film itself and the interfacial thermal resistances of the interfaces between the film and the adjacent materials. When the thickness of the film exceeds a predetermined thickness, the overall thermal resistance of the film is dominated by the intrinsic thermal resistance of the film, which is strongly dependent on its crystalline quality. It is believed that the metal nitride films produced by the method according to the invention have excellent crystalline quality and low intrinsic thermal resistance.

With the details of the preferred embodiments described above, it can be clearly understood that distinguishable from the metal nitride film manufactured by the ALD process using a mixture of nitrogen and hydrogen (N₂/H₂) plasma in the prior art, the method according to the invention not only manufactures the metal nitride film by an ALD process, but also supplies the hydrogen plasma and the nitrogen plasma at different times in a time sequence. The metal nitride film manufactured by the method according to the invention has excellent crystalline quality.

With the example and explanations described above, the characteristics and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of manufacturing a film of a metal nitride on a device, the metal nitride consisting of a metal element, said method being performed by at least one atomic layer deposition cycle, each atomic layer deposition cycle comprising the steps of:
(a) performing at least one half cycle associated with the metal element, and in each half cycle, supplying a precursor containing the metal element into a reaction chamber and then selectively supplying a purge gas into the reaction chamber, wherein the device is placed in the reaction chamber;
(b) supplying a hydrogen plasma into the reaction chamber;
(c) supplying a nitrogen plasma into the reaction chamber; and
(d) supplying the purge gas into the reaction chamber.

2. The method of claim 1, wherein the at least one atomic layer deposition cycle is performed at a film deposition temperature and a working pressure, the film deposition temperature ranges from 100° C. to 700° C. and the working pressure ranges from 0.1 Pa to 1000 Pa.

3. The method of claim 2, between step (b) and step (c), further comprising the step of:
supplying the purge gas into the reaction chamber.

4. The method of claim 2, wherein the film of the metal nitride is one selected from the group consisting of an AlNₓ film, a TiNₓ film, a GaNₓ film, an InNₓ film, a HfNₓ film, a ZrNₓ film, a SiNₓ film, a GeNₓ film, a LaNₓ film, a TaNₓ film, a NbNₓ film, a BNₓ film, a WNₓ film, and a MoNₓ film, 0.5≤x≤1.5, when the film of the metal nitride is the AlNₓ film, a first full width at half-maximum (FWHM) of a first X-ray rocking curve of an AlN(0002) diffraction peak of the AlNₓ film is equal to or less than 300 arcsec, when the film of the metal nitride is the TiNₓ film, a second full width at half maximum (FWHM) of a second X-ray rocking curve of a TiN(111) diffraction peak of the TiNₓ film is equal to or less than 300 arcsec, when the film of the metal nitride is the GaNₓ film, a third full width at half maximum (FWHM) of a third X-ray rocking curve of a GaN(0002) diffraction peak of the GaNₓ film is equal to or less than 300 arcsec.

5. A method of manufacturing a film of a metal nitride on a device, the metal nitride consisting of a metal element, said method being performed by at least one atomic layer deposition cycle, each atomic layer deposition cycle comprising the steps of:
(a) performing at least one half cycle associated with the metal element, and in each half cycle, supplying a precursor containing the metal element into a reaction chamber and then selectively supplying a purge gas into the reaction chamber, wherein the device is placed in the reaction chamber;
(b) supplying a nitrogen plasma into the reaction chamber;
(c) supplying a hydrogen plasma into the reaction chamber; and
(d) supplying the purge gas into the reaction chamber.

6. The method of claim 5, wherein the at least one atomic layer deposition cycle is performed at a film deposition temperature and a working pressure, the film deposition temperature ranges from 100° C. to 700° C. and the working pressure ranges from 0.1 Pa to 1000 Pa.

7. The method of claim 6, between step (b) and step (c), further comprising the step of:
supplying the purge gas into the reaction chamber.

8. The method of claim 6, wherein the film of the metal nitride is one selected from the group consisting of an AlNₓ film, a TiNₓ film, a GaNₓ film, an InNₓ film, a HfNₓ film, a ZrNₓ film, a SiNₓ film, a GeNₓ film, a LaNₓ film, a TaNₓ film, a NbNₓ film, a BNₓ film, a WNₓ film, and a MoNₓ film, 0.5≤x≤51.5, when the film of the metal nitride is the AlNₓ film, a first full width at half-maximum (FWHM of a first X-ray rocking curve of an AlN(0002) diffraction peak of the AlNₓ film is equal to or less than 300 arcsec, when the film of the metal nitride is the TiNₓ film, a second full width at half-maximum (FWHM) of a second X-ray rocking curve of a TiN(111) diffraction peak of the TiNₓ film is equal to or less than 300 arcsec, when the film of the metal nitride is the GaNₓ film, a third full width at half-maximum (FWHM) of a third X-ray rocking curve of a GaN(0002) diffraction peak of the GaNx film is equal to or less than 300 arcsec.
